(19) United States
(12) Patent Application Publication
(10) Pub. No.: US 2026/0052920 A1
(43) Pub. Date: Feb. 19, 2026

(54) System and Method for Enhanced Atomic Layer Etching Process with a Single Process Gas

(71) Applicant: Yang Pan, SINGAPORE (SG)

(72) Inventor: Yang Pan, SINGAPORE (SG)

(73) Assignee: Inspiring Atoms Pte Ltd, SINGAPORE (SG)

(21) Appl. No.: 18/809,249

(22) Filed: Aug. 19, 2024

(51) Int. Cl. H01L 21/3065; H01J 37/32

(52) U.S. Cl. CPC H01L 21/3065; H01J 37/32128; H01J 37/32155; H01J 37/3244; H01J 2237/3341

(57) ABSTRACT

Disclosed herein is a method and system for atomic layer etching (ALE) that utilizes a single gas or a single mixture of gases throughout the process to enhance efficiency. The method involves designing the step times for surface modification and sputtering, with durations specifically tailored to minimize any additional surface modification during the sputtering step. A key innovation is the use of a tailored waveform generator, which provides rapid and precise control of the substrate bias. This technique significantly reduces ALE cycle time while maintaining high precision in semiconductor fabrication.

### BACKGROUND OF THE INVENTION

### 1. Field of the Invention

The present invention pertains to the field of semiconductor manufacturing, more specifically to Atomic Layer Etching (ALE) techniques used in semiconductor device fabrication. The invention focuses on optimizing the ALE process using a single gas or a single mixed gas composition throughout the ALE process, and the design of process parameters, particularly the timing of surface modification and sputtering steps.

### 2. Description of the Prior Art

Reactive ion etching (RIE) is a predominant technology in semiconductor manufacturing. In RIE, diverse species including neutrals, radicals, and ions concurrently influence the etching process. A key characteristic of RIE is the synergistic interaction between ion and neutral fluxes, which significantly enhances the etching rate. This synergistic effect was first described by Coburn and Winters in “Ion- and electron-assisted gas-surface chemistry—an important effect in plasma etching,” published in J. Appl. Phys., vol. 50, pages 3189-3196 (1979). They reported increased silicon etching rates when using an argon ion beam, a XeF2 neutral beam, and their combination. Further, Gottscho et al., in “Microscopic uniformity in plasma etching” (J. Vac. Sci. Technol., B10, pages 2133-2147, 1992), developed a model to quantify this synergy for the etching rate ER:

$$ER = \frac{{vE}_{i} {J}_{i}}{1 + ( {vE}_{i} {J}_{i} ) / ( {v}_{n} {sJ}_{n} )} ,$$

where U represents the volume removed per unit bombardment energy for a saturated surface (cm³/eV), Eᵢ the ion energy (eV), Jᵢ the ion flux to the surface (cm²/s), vₙ the volume removed per reacting neutral (cm³), Jₙ the neutral flux to the surface and s the sticking probability of the neutral species on the bare surface.

Achieving effective RIE necessitates the presence of both ion and neutral fluxes to exploit the synergy identified by Coburn and Winters. However, it is increasingly complex in modern etching apparatus to balance these fluxes, particularly for etching high aspect ratio structures with dimensions shrinking to nanometer scale. Uniform results across 300 mm wafers and consistent repeatability in production pose additional challenges.

Over the past several decades, advancements in etching apparatus features have been made to enhance uniformity. For instance, the evolution of plasma sources from a single coil (U.S. Pat. No. 4,948,458 to Ogle) to multiple coils (U.S. Pat. No. 6,164,241 to Chen et al.) has been notable, either in the form of inductively coupled plasma (ICP) or transformer coupled plasma (TCP). Additionally, gas injection techniques have improved, incorporating multiple injection points to ensure a uniform plasma within the vacuum reactor, as described in U.S. Pat. No. 8,231,799 to Bera et al. and 10,825,659 to Treadwell. Further enhancements include optimizing the electrostatic chuck (ESC) to feature multiple zones with independently adjustable temperatures (U.S. Pat. No. 9,713,200 to Pease and 10,056,225 to Gaff et al.).

A radio frequency (RF) power generator, coupled to the ESC, provides a bias for the ions in the plasma in addition to the plasma sheath. This coupling, facilitated through a blocking capacitor, helps establish a stable plasma sheath by preventing electron flow to the ground, as detailed in U.S. Pat. No. 5,302,240 to Hori et al. Moreover, various pulsing schemes for RF power generators have been implemented to improve ion energy and angular distribution, thereby maximizing the synergetic effects between ions and neutrals, as described in U.S. Pat. No. 8,264,154 to Banner et al. and 10,121,639 to Kanarik. RF power generators with tailored waveforms, as discussed by Wang et al. in “Experimental demonstration of multifrequency impedance matching for tailored voltage waveform plasmas” (J. Vac. Sci. Technol. A37, 021303, pages 1-11, 2019), have also been employed to precisely control ion energy.

Additionally, gases can be pulsed in a cyclic process to enhance performance, as disclosed in U.S. Pat. No. 10,121,639 to Kanarik. This cyclic approach segments the RIE process into steps, each optimized with a different set of process gases.

Despite these improvements, achieving the required uniformity across a 300 mm wafer for critical dimension (CD), loading, and profile remains a significant challenge, often entailing considerable expense.

ALE has been developed to address the limitations of RIE. ALE apparatus has evolved from the RIE apparatus with less stringent requirements for achieving uniformity on a 300 mm wafer. However, ALE has unique requirements due to the nature of its process steps.

An overview of ALE technology is presented by Karanik et al. in “Overview of atomic layer etching in the semiconductor industry” (J. Vac. Sci. Technol. A33, pages 020802 1-14, 2015), and further discussed in a book by Lill, “Atomic layer processing: semiconductor dry etching technology” (Wiley-VCH GmbH, Boschstr. 12, 69469 Weinheim, Germany, 2021). ALE facilitates the controlled removal of material layers with atomic-level precision and is characterized as an etching technique using sequential self-limiting reactions. The basic ALE process includes two steps: surface modification and material removal. The modification creates a thin reactive layer with a defined thickness, which is easier to remove than the unmodified material. The removal step eliminates this modified layer while preserving the underlying substrate, thus resetting the surface for subsequent cycles. The material removal is quantified over multiple cycles and can be achieved using thermal energy by raising the wafer's temperature or kinetic energy from ions typically derived from inert gases. The isotropic process using thermal energy to remove modified layers is described in U.S. Pat. No. 10,208,383 to George et al. When utilizing energetic ions, the removal is conducted via a sputtering process.

The anisotropic ALE process, which is the focus of the present invention, has been employed for etching various materials, demonstrating the technology's versatility:
Si and Ge as described in U.S. Pat. No. 10,727,073 to Tan et al.,
SiO2 as described in U.S. Pat. No. 9,620,382 to Oehrlein et al.,
C as described in U.S. Pat. Pub. Nos. 2017/0316935 and 2022/0216050 by Tan et al.,
W as described in U.S. Pat. Pub. No. 2020/0286743 from Lai et al and U.S. Pat. No. 10,096,487 to Yang et al,
Co as described in U.S. Pat. No. 10,096,487 to Yang et al,
Ru as described in U.S. Pat. Pub. No. 2022/0199422 by Yang et al.,
Other refractory metals and materials with high surface binding energy as described in U.S. Pat. No. 11,450,513 to Yang et al.,
Cu as described in WO Pat. Pub. No. 2022/046429 by Yang et al.,
GaN and other III-V materials as described in U.S. Pat. No. 10,056,264 to Yang et al.,
MRAM as described in U.S. Pat. No. 10,749,103 to Tan et al.,
EUV patterning as described in U.S. Pat. No. 9,922,839 to Wise et al., and
Surface smoothing of various materials as described in U.S. Pat. No. 10,304,659 to Karanik et al.

It should also be noted that a deposition component in the ALE steps or an independent deposition step is often introduced in the ALE process to enhance its performance, especially for controlling the profile of structures being etched. For example, selective deposition on a carbon-containing material is applied to improve ALE performance as described in U.S. Pat. Pub. No. 2017/0316935 by Tan et al. Additionally, as disclosed in U.S. Pat. No. 9,805,941 to Karanik et al., atomic layer deposition (ALD) and ALE are conducted from a single plasma process chamber. This method involves sequentially alternating between ALE and ALD processes to prevent feature degradation during etching, improve selectivity, and encapsulate sensitive layers of a semiconductor substrate.

The distinct chemistry, speciation, and plasma energy composition involved in the surface modification and sputtering steps enhance the process by enabling more controlled ion, electron, and neutral species fluxes, thereby widening the process window. This separation facilitates self-limiting reactions, crucial for maintaining the ideality of the etching process-characterized by uniformity, smoothness, and selectivity. Karanik et al. in “Predicting synergy in atomic layer etching” (J. Vac. Sci. Technol. A35, pages 05C302 1-7, 2017) defined ALE synergy as:

$${ALE}_{synergy} S ( \% ) = \frac{EPC - ( α + β )}{EPC} \times 100 \%$$

EPC is “etch per cycle” representing the total thickness of material removed in one cycle, typically averaged over many cycles. The values of “α” and “β” are (undesirable) contributions from the surface modification step and the sputtering step, respectively. Ideally, synergy will approach 100% with no etching from either step alone. In practice, RIE in the surface modification step are nonzero because of presence of ions in the plasma which generates neutrals to modify the surface. In the sputtering step, physical sputtering of underlying unmodified layer is also nonzero.

It is desirable for the plasma in the surface modification step of the ALE process to be free from ion bombardment. However, the unintended introduction of RIE components during this step presents a persistent challenge. This issue stems from the difficulty in completely preventing ion bombardment of the substrate surface, compromising the ideality of the ALE processes. Modern ALE methodologies struggle to effectively eliminate these RIE components, leading to suboptimal etching outcomes, particularly as device geometries become more complex and smaller in scale. The presence of RIE components in ALE processes can result in non-uniform layer removal and undesirable etching profiles, which are especially problematic in advanced device manufacturing where even minor deviations can significantly impact device performance and yield.

One solution to this problem, as disclosed in U.S. Pat. No. 9,362,131 to Agarwal et al., involves using an electron beam source. During the passivation step (surface modification step), a remote plasma source supplies passivation species to the main process chamber while keeping ion energy below the etching threshold. During the etching operations, the flow from the remote plasma source is stopped, and the ion energy is raised above the etch threshold. This approach introduces an additional remote source. It complicates the apparatus and may increase the cost of the process.

In addition to tackling challenges related to achieving higher synergy in ALE, efforts have been made to enhance the speed of the ALE process. For instance, high-energy ions, more than 150 eV, are used to remove the modified surface layer as disclosed in U.S. Pat. No. 10,763,083 to Yang et al. Furthermore, pulsing has been applied to an RF power generator coupled to the electrostatic chuck (ESC) to provide a bias for the ions in the plasma. In another development disclosed in WO Pat. Pub. No. 2023/183129, the sputtering time in the sputtering step has been reduced to a range between 10 ms and 600 ms.

Another approach to increasing the speed of ALE involves relaxing the requirements for self-limiting reactions, as disclosed in TW Pat. No. 1757334 to Cottle et al. While this method accelerates the ALE process, it may reduce the synergy factor, thereby degrading the performance of ALE.

The standard practice in ALE involves modulating multiple gases' flow rates using mass flow controllers (MFCs). This modulation is typically dynamic, requiring constant adjustments to maintain optimal etching conditions, which adds complexity and potential for inconsistency in the etching process. Additionally, the transitioning between different etching steps, such as from surface modification to sputtering, often necessitates complete gas exchanges, further prolonging the overall process cycle time.

Moreover, the reliance on frequent adjustments for gas flow rates and valve positions during production runs leads to inefficiencies and variations in process outcomes. These factors limit the throughput and scalability of conventional ALE processes, posing a bottleneck in high-volume semiconductor manufacturing.

It is in this context, there is a clear need for innovations in the ALE process that streamline gas management, reduce cycle time, and enhance the consistency of etching outcomes. The present invention addresses these needs by introducing a novel ALE method that utilizes a single gas or a single mixed gas composition throughout the process, thereby simplifying gas management and reducing cycle time. Furthermore, the invention leverages a tailored waveform generator to provide precise control over the substrate bias, crucial for shortening of the time required for the sputtering step of the ALE process to minimize additional modification of the surface by neutrals. This approach represents a significant advancement in the field of semiconductor manufacturing, offering enhanced process efficiency and precision.

### SUMMARY

The present invention introduces an advanced method in the field of atomic layer etching (ALE), characterized by the novel use of a single gas or a single mixed gas composition throughout the entire ALE process. In some embodiments, this approach significantly streamlines the etching procedure, resulting in a substantial reduction in cycle time and an increase in overall efficiency. A pivotal aspect of this invention, as implemented in various embodiments, is designing of durations for two critical steps: the surface modification step and the sputtering step. During the surface modification step, the substrate's surface is exposed to plasma for a specific duration, ensuring the formation of a modified layer. This is followed by the sputtering step, where the duration is strategically designed to be long enough to remove the previously modified layer while being carefully controlled to minimize any further surface modification. This delicate balance is crucial for maintaining the precision and effectiveness of the ALE process, even when using a single process gas, typically containing chemically reactive neutrals within the generated plasma.

A key feature of this invention, as utilized in various embodiments, is the incorporation of a tailored waveform generator. This component is integral to establishing and maintaining a precise substrate bias almost instantaneously, which is essential for controlled ion acceleration during the sputtering step. In certain implementations, the tailored waveform generator allows for the rapid establishment and adjustment of the bias, providing the necessary control to achieve the desired etching precision with minimal delay.

Furthermore, in specific embodiments, the invention optimizes the chamber operational parameters, such as chamber pressure, RF power for the plasma source, and bias settings, to align with the requirements of streamlined gas usage and the tailored timing of the etching steps. This optimization ensures that the ALE process is conducted under the most favorable conditions, further enhancing process efficiency.

In summary, this invention presents a method for improving the ALE process by utilizing a single gas or mixed gas composition, combined with optimized timing and control of the surface modification and sputtering steps, and supported by the implementation of a tailored waveform generator. These features, as incorporated in various embodiments and implementations, significantly enhance the efficiency and precision of the ALE process.

### BRIEF DESCRIPTIONS OF THE DRAWINGS

To provide enhanced clarity, the following description references the accompanying drawings:

FIG. 1 illustrates an exemplary process system for ALE.

FIG. 2 depicts the waveforms of the plasma source, the substrate bias, the output of the tailored waveform generator, and the gases used in the ALE process.

FIG. 3 presents a flowchart of the ALE process according to one embodiment.

### DETAILED DESCRIPTIONS

To ensure comprehensive understanding, this section delves into detailed embodiments of the present invention. Although certain specifics are provided for clarity, modifications and variations that align with the subsequent claims are deemed appropriate. Conventional methods and components are highlighted to underscore the distinct features of the invention. Terms used are defined as follows:

Anisotropic ALE (or simply “ALE”): Refers to an etching process used in semiconductor manufacturing that removes material layer by layer at the atomic scale, offering high control over etch depth and profile. ALE operates in cycles, each consisting of a surface modification step and a sputtering step. The surface modification step involves chemically altering the surface of the material to form a reactive layer, preparing it for selective removal in the subsequent sputtering step, where physical ion bombardment removes the modified layer, ensuring high precision and selectivity in etching.

Aspect Ratio: Represents the ratio of the height to the width of a feature on a semiconductor wafer, critical in defining the geometry and performance of microstructures.

Bias Unit: Refers to the component that generates a controlled voltage to accelerate ions towards the wafer held by an electrostatic chuck (ESC). This voltage creates an electric field that enhances ion bombardment, crucial for precise control of ion energy and directionality in processes like etching.

Chamber: An enclosed environment within process equipment where semiconductor manufacturing processes, such as etching or deposition, occur.

Chuck: A component in semiconductor manufacturing equipment that holds and secures the wafer in place during processing.

Dielectric Window: In a vacuum chamber, this is a non-conductive, transparent or semi-transparent barrier that separates the plasma generation region from external components while allowing electromagnetic waves, such as RF or microwave energy, to pass through.

ESC (Electrostatic Chuck): A type of chuck that uses electrostatic forces to hold the wafer in place during semiconductor manufacturing processes, providing uniform clamping and stability.

Gas Distribution Unit: A component in a vacuum process chamber designed to introduce and distribute process gases uniformly across a substrate. For example, an injector can be positioned either centrally or at specific points or angles, allowing for controlled gas delivery to targeted areas. A showerhead, typically featuring a perforated plate, disperses gas evenly across the substrate, ensuring consistent exposure during processes like ALE. Additionally, a side injection mechanism introduces gas from the chamber's sides, promoting lateral flow and even distribution.

Gas Source: The origin or supply point of process gases used in a vacuum process chamber, typically connected to a facility's centralized gas distribution system. For instance, a gas box regulates and controls the flow of specific gases, delivering them under controlled pressure and flow conditions into the process chamber, ensuring appropriate gas composition and purity for the desired process.

High Aspect Ratio: Refers to features on a semiconductor wafer with a significantly greater height compared to their width, often challenging to manufacture due to difficulty in achieving uniformity and precision.

PID Control: A control loop mechanism employing proportional-integral-derivative (PID) actions to regulate a process. In semiconductor manufacturing, PID controllers maintain precise control over variables such as temperature, pressure, and gas flow. The proportional component adjusts control output based on current error, the integral component corrects past cumulative errors, and the derivative component anticipates future errors based on the rate of change, ensuring stable and accurate process conditions.

Plasma Process Chamber: A specialized type of vacuum chamber designed for processes involving plasma, a highly ionized gas. In semiconductor manufacturing, these chambers are used for etching and deposition, where plasma provides the energy needed to activate chemical reactions or remove material from the wafer surface.

Plasma Source: A device that generates plasma for use in semiconductor manufacturing processes like etching, deposition, and surface modification. Common types include inductively coupled plasma (ICP), transformer coupled plasma (TCP), and capacitively coupled plasma (CCP). ICP uses an RF magnetic field from a coil to produce plasma. TCP employs a planar coil and RF energy to create plasma through transformer action. CCP generates plasma by applying RF power across two electrodes, creating an electric field that ionizes the gas.

Process System: The integrated equipment and machinery used in semiconductor manufacturing to carry out various processes such as deposition, etching, and cleaning.

Pulsing: A technique of modulating RF power in pulses rather than a continuous wave, allowing for better control over the energy delivered to the plasma and enhancing process outcomes such as etching precision and uniformity.

Pulse Train: In the context of a tailored waveform, this refers to a sequence of pulses with precisely controlled amplitude, duration, timing, and slope for a ramp step, designed to form a specific waveform profile.

Reactive Ion Etching (RIE): A plasma-based etching technique used in semiconductor manufacturing where both physical ion bombardment and chemical reactions work synergistically to remove material from a substrate. In RIE, a reactive gas is ionized in plasma, creating a mix of ions and neutral species. The ions are accelerated towards the substrate by an electric field, where they physically sputter material, while the chemically reactive neutrals enhance etching.

Resonator: A device or circuit component designed to resonate at a specific radio frequency, crucial for applications like RF impedance matching in RF circuits. Resonators can be constructed using various technologies like LC circuits (inductor-capacitor circuits) and are used to provide high selectivity and stability at their resonant frequency.

RF Power Generator: A device that generates radio frequency power used in semiconductor manufacturing processes to energize plasma for etching or deposition.

Sheath: In plasma, the boundary layer between the plasma and a surface, where a strong electric field forms. This region controls the energy and flux of ions and electrons reaching the surface, crucially influencing processes like etching and deposition in semiconductor manufacturing.

Substrate: The base material, typically a silicon wafer, upon which semiconductor devices are fabricated.

System Controller: The central unit that manages and controls the various operations and parameters of semiconductor manufacturing process systems, ensuring coordinated and efficient functioning.

Tailored Waveform Generator: A device that produces custom-designed electrical waveforms to optimize plasma processes in semiconductor manufacturing. By adjusting the shape, frequency, and amplitude of the waveforms, it allows precise control over plasma characteristics, enhancing etching and deposition performance, uniformity, and selectivity.

Transmission Line (in RF): A specialized conductor or set of conductors designed to carry radio frequency (RF) signals with minimal loss and distortion. In semiconductor manufacturing, transmission lines efficiently transfer RF power from the generator to the plasma source or other RF components. They ensure impedance matching to minimize reflections and power losses, enabling precise and reliable delivery of RF energy for processes like etching and deposition.

Vacuum Chamber: An enclosed space from which air and other gases are removed to create a low-pressure environment. Used in semiconductor manufacturing to conduct processes requiring controlled atmospheric conditions, such as deposition and etching, to prevent contamination and ensure precision.

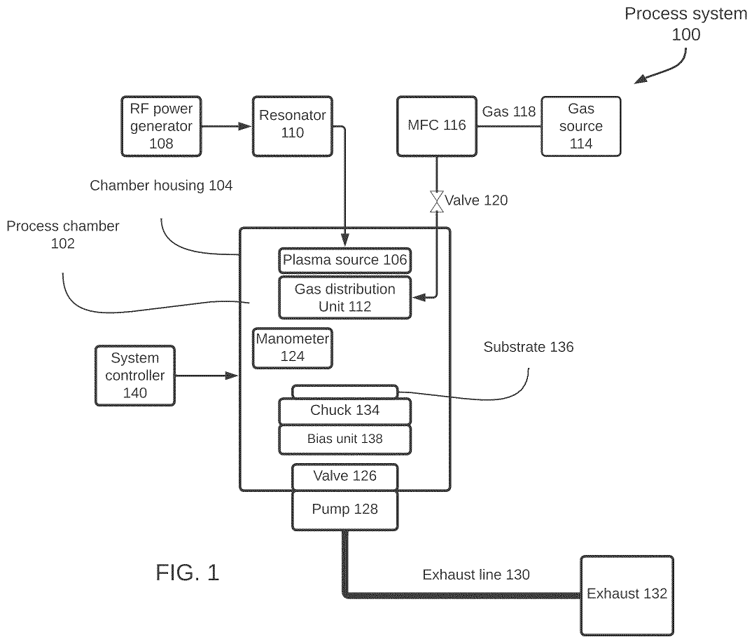

FIG. 1 illustrates an exemplary atomic layer etching (ALE) process system, designated as process system 100. This system includes a process chamber, referred to as 102, with its operations coordinated by a system controller, identified as 140. The chamber 102 is enclosed by a chamber housing, marked as 104, which creates a vacuum environment suitable for plasma processing. The chamber housing 104, potentially constructed from materials such as aluminum or quartz, may feature an aluminum interior surface treated with processes like anodization or coated with yttrium oxide to enhance resistance to the plasma environment.

Positioned atop the chamber housing 104 is a plasma source, labeled as 106. Beneath the plasma source 106 (not shown in the figure) is a dielectric window that hermetically seals the chamber 102. This window, possibly made from materials such as quartz or ceramics, may have an interior surface coated with a plasma-resistant material like yttrium oxide. The plasma source 106 can take various forms, such as an inductively coupled plasma (ICP) or transformer coupled plasma (TCP) source and may include configurations like a multiple-turn coil or coils, which can be cylindrical or conical in shape.

The plasma source 106 is functionally connected to an RF power generator, denoted as 108, through a resonator 110. The RF power generator 108 can produce RF power at single or multiple frequencies, including but not limited to 100 kHz, 200 kHz, 400 kHz, 2 MHz, 13.56 MHz, 27 MHz, 40 MHz, and 60 MHz. The resonator 110 plays a crucial role in matching the output impedance of the RF power generator 108 with the plasma load of chamber 102, accounting for transmission line effects.

A gas distribution unit, referred to as 112, is connected to a gas source 114 via a mass flow controller (MFC, 116). The gas source 114 supplies a gas 118 to the gas distribution unit 112. A valve 120 is located between the MFC 116 and the gas distribution unit 112. In some embodiments, the gas 118 may be a single substance, such as chlorine for silicon etching, or a mixture, such as chlorine and argon, or oxygen and argon. A distinctive feature of this invention is the use of either a single gas or a single gas mixture throughout the ALE process, significantly reducing the cycle time by eliminating the need for gas exchange.

The MFC 116 along the gas path controls the flow rate of the gas 118. In some implementations, a manifold (not depicted in the figure) may be used to mix gases before they are introduced into the gas distribution unit 112.

The gas source 114 may include various gas delivery mechanisms, such as a gas box. Depending on the specific embodiment, the gas distribution unit 112 can function either as an injector or as a showerhead. In some configurations, the dielectric window integrates with the gas distribution unit 112, serving as a showerhead while also sealing the chamber 102. A manometer, designated as 124, measures the pressure inside the process chamber 102.

In certain implementations, the gas distribution unit 112 may further include gas injection points from the interior sidewall of the process chamber 102.

Additionally, the process chamber 102 includes a pump, labeled as 128, and a valve, denoted as 126. The pump 128, which may be a turbo molecular pump (TMP) in certain implementations, is tasked with extracting unused gases and reaction byproducts from the process chamber 102, expelling them through an exhaust line 130 to an exhaust system 132. The position of a movable part, like a cover of the valve 126, plays a crucial role in determining the rate of gas extraction in tandem with the pump 128.

The position of the movable part of the valve 126 is key in establishing gas conductance, working in conjunction with the pump 128's capacity. To adjust the valve's position, an actuator controlled by a valve controller is used. This controller employs a proportional-integral-derivative (PID) control mechanism to determine the necessary position of the movable part to maintain steady-state chamber pressure, in coordination with the system controller 140. Typically, the PID control may take several hundred milliseconds to correctly position the movable part, which can limit the cycle time of the ALE process, especially during gas exchanges. Thus, minimizing or eliminating the need for gas exchanges is advantageous for enhancing process efficiency.

The system controller 140 manages the MFC 116, the pump 128, and the valve 126 to maintain steady-state chamber pressure, as monitored by the manometer 124.

The process chamber 102 also incorporates a chuck, identified as 134, which functions as a support structure for a substrate, indicated as 136. The chuck 134 can be designed in various forms, such as an electrostatic chuck (ESC) or a vacuum chuck. Connected to the chuck 134 is a bias unit, marked as 138, which provides a bias to the substrate. This bias unit 138 is crucial for controlling ion energy during the process and can be an RF power generator operating at frequencies ranging from 100 kHz to 60 MHz. In such configurations, a resonator is used to match the impedance between the RF generator's output and the load impedance of the process chamber 102 via the chuck 134. A blocking capacitor may be employed to establish a steady-state bias for the chuck 134. While it is a known technique to establish such a bias, a limitation is that the steady-state bias cannot be achieved instantaneously, typically requiring several tens of milliseconds to establish.

In the context of the present invention, a much shorter sputtering step is required after the substrate surface 136 undergoes a neutral particle-induced surface modification step. This abbreviated duration is critical to avoid re-modifying the surface, which could inadvertently induce reactive ion etching (RIE) during the sputtering step.

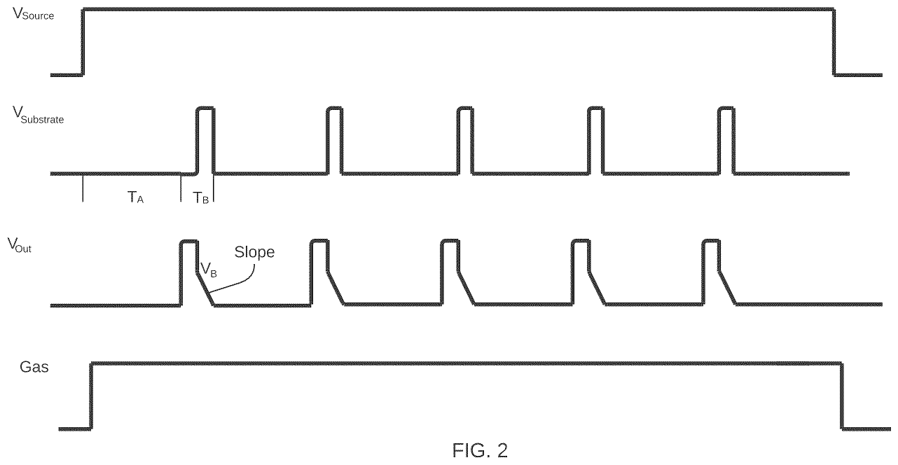

Consequently, the preferred embodiment of the present invention involves using a tailored waveform generator to supply the bias for the substrate 136. This tailored waveform generator can establish the bias for the substrate in a range of microseconds or less. It maintains the bias by applying a negatively ramped voltage, as illustrated in FIG. 2. In this preferred embodiment, the sputtering step comprises a pulse train of tailored waveforms, each pulse delivering a steady substrate bias with a duration of a few microseconds or less. For such a short duration, the energetic ions remove only a small portion of the modified layer via physical sputtering. Additionally, the sputtering step time is designed to allow the modified layer to be removed without inducing further surface modification by the neutrals.

FIG. 2 illustrates exemplarily the waveforms of the plasma source Vsource, the substrate bias VSubstrate, and the output of the tailored waveform generator Vout. At the bottom of FIG. 2, the flow of either the single gas or the single mixed gases are depicted. The output from the tailored waveform generator initiates with a brief positive voltage spike, aimed at neutralizing trapped positive charges by electrons on the substrate from the preceding pulse. Subsequently, the generator applies a negative bias VB, followed by a period of ramping down to a more negative voltage. This ramping down is designed to compensate for trapped positive charges by ions, maintaining a constant substrate bias Vsubstrate for ion acceleration, as shown in FIG. 2. For the simplicity, only one of the tailored waveforms is depicted in FIG. 2 for illustration during the sputtering step. There may be many such waveforms like thousands as appropriate for a specific application. Further, the ALE process may have various cycles depending on specific applications.

The surface modification step is characterized by a duration T_{A}, and the sputtering step by a duration T_{B}. In an ALE process chamber, the gap between the gas distribution unit 112 and the chuck 134 typically ranges from 3 to 30 centimeters. It requires approximately 20 to 200 milliseconds for neutrals to diffuse from a point near the plasma source inside the process chamber 102 to the substrate 136, held by the chuck 134. Theoretically, the surface reaction can take milliseconds to complete as illustrated in a paper published by Karanik et al., “Atomic layer etching: rethinking the art of etch”, (J. Phys. Chem Lett. vol. 9, 2018, pp. 4814-4821). Considering practical factors, an additional 30 to 300 milliseconds maybe needed for the neutrals to diffuse and to penetrate the bottom of a structure being etched and react with the surface atoms. Therefore, T_{A} is ideally set between 50 to 500 milliseconds depending on a volume of the chamber and the aspect ratio of structures to be etched in the substrate. T_{B} is designed to be between 10 to 50 milliseconds, allowing sufficient time to remove the modified layer with ions while minimizing further surface modification during the sputtering step. The chamber pressure, RF power for the plasma source, and the bias are selected to fulfill these requirements during the sputtering step.

In FIG. 2, a constant RF power is illustrated exemplarily throughout the ALE process for the plasma source 106. The power at the surface modification step can be pulsed at a predetermined frequency from 100 Hz to 100 kHz, with a duty cycle ranging from 1% to 50%. The RF power for the plasma source 106 at the sputtering step may be different from the RF power at the surface modification step. In some implementations, the RF power at the sputtering step is higher than the power at the modification step. The increased power will help to reduce required sputtering time by increasing the ion density in the plasma. In some other implementations, the RF power at the sputtering step is lower than the power at the modification step. The reduced power will help to reduce neutral density and to reduce chance of additional surface modification. However, the ion density will also be reduced, which will need longer time to remove the modified layer. The precise process window of the applied RF power for the plasma source 106 and timing for the steps may be determined by a simulation which takes account related factors and decide an optimal parameter set for the ALE process. Alternatively, the parameters can be determined by a test based on design of experiments (DOE).

Since the single gas or the single mixed gases is used throughout the ALE process, a chamber pressure needs to be designed. Higher pressure will reduce the surface modification time at the surface modification step and increase ion density at the sputtering step. However, it will cause larger ion angular distribution as known in the art. The ideal chamber pressure can in a range between 1 mTorr to 500 mTorr. The exact value will depend on specific applications.

In an alternative implementation, the chamber pressure maybe modulated by the system controller 140 without changing the gas or the gases. For example, the gas pressure during the sputtering step can be set to a lower value than the pressure during the surface modification step. This can be accomplished by either changing the gas flow rate by the MFC 116 or adjusting the position of the movable part of the valve 126.

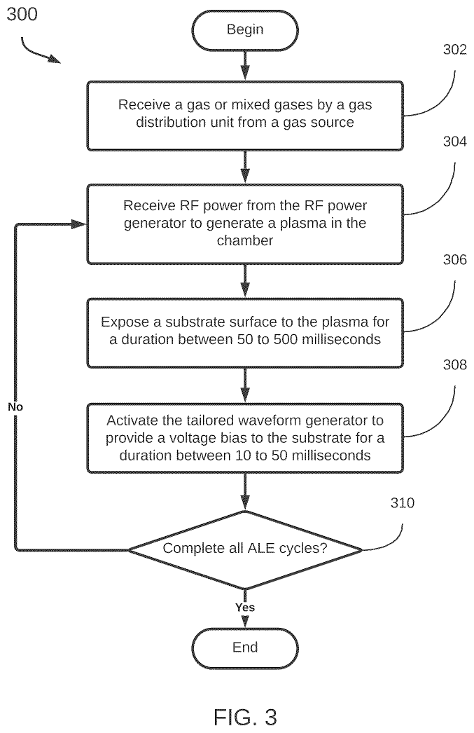

An exemplary ALE process, labeled as process 300, is depicted in FIG. 3. This process 300 begins with step 302, where a single gas or a single mixed gas 118 is introduced into the gas distribution unit 112. In an exemplary scenario for silicon ALE, chlorine is used as the gas, with the flow rate managed between 50 to 500 SCCM by the MFC 116, sourced from the gas source

In step 304, RF power for the surface modification step is supplied to the plasma source 106 by the RF power generator 108. This RF power includes at least one frequency within the range of 100 kHz to 60 MHz, with power levels ranging from 50 watts to 5000 watts. In one implementation, the RF power remains constant throughout the modification step. Alternatively, the RF power may be pulsed at a predetermined frequency between 100 Hz and 100 kHz, with a duty cycle ranging from 1% to 50% during the surface modification step.

In step 306, the surface of the substrate 136 is exposed to the plasma for 50 to 500 milliseconds to complete the surface modification step. Moving on to the sputtering step at step 308, in a preferred embodiment, the tailored waveform generator is activated to provide bias to the substrate for 10 to 50 milliseconds via a pulse train comprising the tailored waveform. This time frame allows the plasma ions, accelerated by the substrate bias, to remove the modified layer while preventing the neutrals in the plasma from having sufficient time to cause additional surface modification. The substrate bias may range from 100 to 10,000 volts.

In step 310, the system controller 140 checks whether all ALE cycles have been completed to conclude process 300. If not, the ALE cycle is repeated.

1. A process system for performing an ALE process, comprising:
a chamber maintaining an interior space for a vacuum environment;
a plasma source coupled to an RF power generator configured to generate plasma in the chamber;
a bias unit operatively connected to a chuck;
a gas distribution unit configured to receive a gas, or mixed gases, continuously throughout the ALE process; and
a system controller configured to operate the process system to conduct the ALE process including a surface modification step and a sputtering step sequentially with the same process gases for both steps, wherein the sputtering step duration is designed to be below a threshold that avoids additional surface modification during the step.

2. The process system of claim 1, wherein the system controller operates the surface modification step with a duration between 50 to 500 milliseconds and the sputtering step with a duration between 10 to 50 milliseconds.

3. The process system of claim 1, wherein the bias unit further includes a tailored waveform generator.

4. The process system of claim 3, wherein the tailored waveform generator provides a voltage bias for a substrate in a range from 100 to 10,000 volts during the sputtering step.

5. The process system of claim 1, wherein the plasma source is further configured to receive RF power from the RF power generator with pulsing at a predetermined frequency from 100 Hz to 100 kHz, and at a duty cycle from 1% to 50% during the surface modification step.

6. The process system of claim 1, wherein the plasma source is further configured to receive RF power, during the sputtering step, at a higher level than the RF power received at the surface modification step.

7. The process system of claim 1, wherein the plasma source is further configured to receive RF power, during the sputtering step, at a lower level than the RF power received at the surface modification step.

8. The process system of claim 1, wherein the controller further operates the chamber at a pressure level in a range from 1 mTorr to 500 mTorr.

9. The process system of claim 1, wherein the gas distribution unit further includes an injector.

10. The process system of claim 1, wherein the gas distribution unit further includes a showerhead.

11. The process system of claim 1, wherein the gas distribution unit further includes an injection mechanism from sidewalls of the chamber.

12. The process system of claim 1, wherein the gas or mixed gases further include at least one halogen.

13. A method for conducting an ALE process in a process system comprising a plasma process chamber, the method executed by a system controller including:
a) introducing a gas or mixed gases into the chamber via a gas distribution unit connected to a gas source;
b) generating plasma in the chamber by applying RF power from an RF power generator;
c) subjecting a substrate surface to the plasma for a duration ranging from 50 to 500 milliseconds to form a modified surface layer;
d) subjecting the substrate surface to ions to remove the modified layer by employing a tailored waveform generator to apply a voltage bias to the substrate for a period between 10 to 50 milliseconds; and
e) repeating steps a) to d) until the completion of the ALE process, wherein the gas or the mixed gases are unchanged through the ALE process.

14. The method of claim 13, wherein, during step d), the tailored waveform generator establishes a voltage bias within a range from 100 to 10,000 volts.

15. The method of claim 13, wherein, in step b), the plasma source is configured to receive continuous RF power from the RF power generator, where the RF power includes at least one frequency in a range from 100 kHz to 60 MHz, and a power level in a range from 50 watts to 5000 watts.

16. The method of claim 13, wherein, in step b), the plasma source is adapted to receive pulsed RF power from the RF generator at a predetermined frequency from 100 Hz to 100 kHz, with a duty cycle ranging from 1% to 50%.

17. The method of claim 13, wherein step d) additionally involves the plasma source receiving RF power from the RF power generator, at a higher level than the power applied in step b).

18. The method of claim 13, wherein step d) additionally involves the plasma source receiving RF power from the RF power generator, at a lower level than the power applied in step b).

19. The method of claim 13, further comprising a step of regulating the chamber pressure to a steady state range from 1 mTorr to 500 mTorr, as controlled by the system controller based on readings from a manometer.

20. The method of claim 13, wherein the gas or mixed gases used in the process include at least one halogen.
